(19) United States
(12) Patent Application Publication
(10) Pub. No.: US 2019/0179387 A1
(43) Pub. Date: Jun. 13, 2019

(54) POWER STORAGE APPARATUS

(71) Applicant: Merry Electronics(Shenzhen) Co., Ltd., ShenZhen (CN)

(72) Inventors: Chih-Chung Lin, Taichung (TW); Wei-Chi Chang, Taichung (TW); Yung-Hsiang Liu, Taichung (TW)

(73) Assignee: Merry Electronics(Shenzhen) Co., Ltd., ShenZhen (CN)

(21) Appl. No.: 16/100,212

(22) Filed: Aug. 10, 2018

Related U.S. Application Data
(60) Provisional application No. 62/598,449, filed on Dec. 13, 2017.

(51) Int. Cl. G06F 1/26; H02M 3/158; G06F 1/28; H01M 10/42

(52) U.S. Cl. CPC G06F 1/263; H02M 3/1582; G01R 31/3606; H01M 10/4257; G06F 1/28

(57) ABSTRACT

A power storage apparatus is provided. The power storage apparatus includes a system host, a battery expansion module, and a communication interface. The system host includes a first switch set and a main battery. The battery expansion module includes a second switch set and an expansion battery. When the system host and the battery expansion module are assembled, an expansion controller and a main controller communicate with each other through the communication interface and selectively control the first switch set and the second switch set to charge the main battery or the expansion battery.

### CROSS-REFERENCE TO RELATED APPLICATION

This application claims the priority benefits of U.S. provisional application Ser. No. 62/598,449, filed on Dec. 13, 2017. The entirety of the above-mentioned patent application is hereby incorporated by reference herein and made a part of this specification.

### BACKGROUND

### Technical Field

The disclosure relates to a power storage apparatus and more particularly relates to an expandable power storage apparatus.

### Description of Related Art

With the advancement of technology, mobile devices are becoming more and more common. As to how to keep mobile devices operating for a long time, power supply and power storage play very important roles.

With the existing battery expansion technology, the battery of a power storage apparatus can be charged by an additional expansion battery to maintain the power of the power storage apparatus. The current expansion form requires the battery of the power storage apparatus and the battery of the expansion device to be connected in parallel. Moreover, the battery of the power storage apparatus and the battery of the expansion device need to be batteries of the same power specification. That is, since the power specifications need to be the same, the flexibility of the existing battery expansion technology is limited.

### SUMMARY

The disclosure provides a power storage apparatus that improves battery expansibility.

The power storage apparatus of the disclosure includes a system host, a battery expansion module, and a communication interface. The system host includes a main controller, a main battery, a first switch set, and a main buck-boost converter. The first switch set is coupled between the main controller and the main battery. The main buck-boost converter is coupled to the main controller, the first switch set, and the main battery. The main buck-boost converter receives control of the main controller, and converts a first DC input voltage received by the first switch set and outputs a first DC output voltage to charge the main battery. The battery expansion module is adapted to be detachably assembled with the system host. The battery expansion module includes an expansion controller, an expansion battery, and a second switch set. The second switch set is coupled between the expansion controller and the expansion battery. When the system host and the battery expansion module are assembled, the expansion controller and the main controller communicate with each other through the communication interface and selectively control switches of the first switch set and the second switch set to charge the main battery or the expansion battery.

Based on the above, the power storage apparatus of the disclosure includes the system host, the battery expansion module, and the communication interface. When the system host and the battery expansion module are assembled, the expansion controller and the main controller communicate with each other through the communication interface and control the first switch set and the second switch set, so as to select to charge the main battery or the expansion battery. In addition, the main buck-boost converter converts the first DC input voltage received by the first switch set and outputs the first DC output voltage to charge the main battery. Thus, the expansibility of the power storage apparatus can increase expansion devices.

To make the aforementioned more comprehensible, several embodiments accompanied with drawings are described in detail as follows.

### BRIEF DESCRIPTION OF THE DRAWINGS

The accompanying drawings are included to provide a further understanding of the disclosure, and are incorporated in and constitute a part of this specification. The drawings illustrate exemplary embodiments of the disclosure and, together with the description, serve to explain the principles of the disclosure.

FIG. 1 is a schematic diagram of the power storage apparatus according to the first embodiment of the disclosure.

FIG. 2 is a schematic diagram of the power storage apparatus according to the second embodiment of the disclosure.

FIG. 3 is a flowchart illustrating an operation that the power storage apparatus performs on the first switch set and the second switch set according to the second embodiment of the disclosure.

FIG. 4 is a schematic diagram of the power storage apparatus according to the third embodiment of the disclosure.

FIG. 5 is a schematic diagram of the power storage apparatus according to the fourth embodiment of the disclosure.

FIG. 6 is a flowchart illustrating an operation that the power storage apparatus performs on the first switch set and the second switch set according to the fourth embodiment of the disclosure.

### DETAILED DESCRIPTION OF DISCLOSED EMBODIMENTS

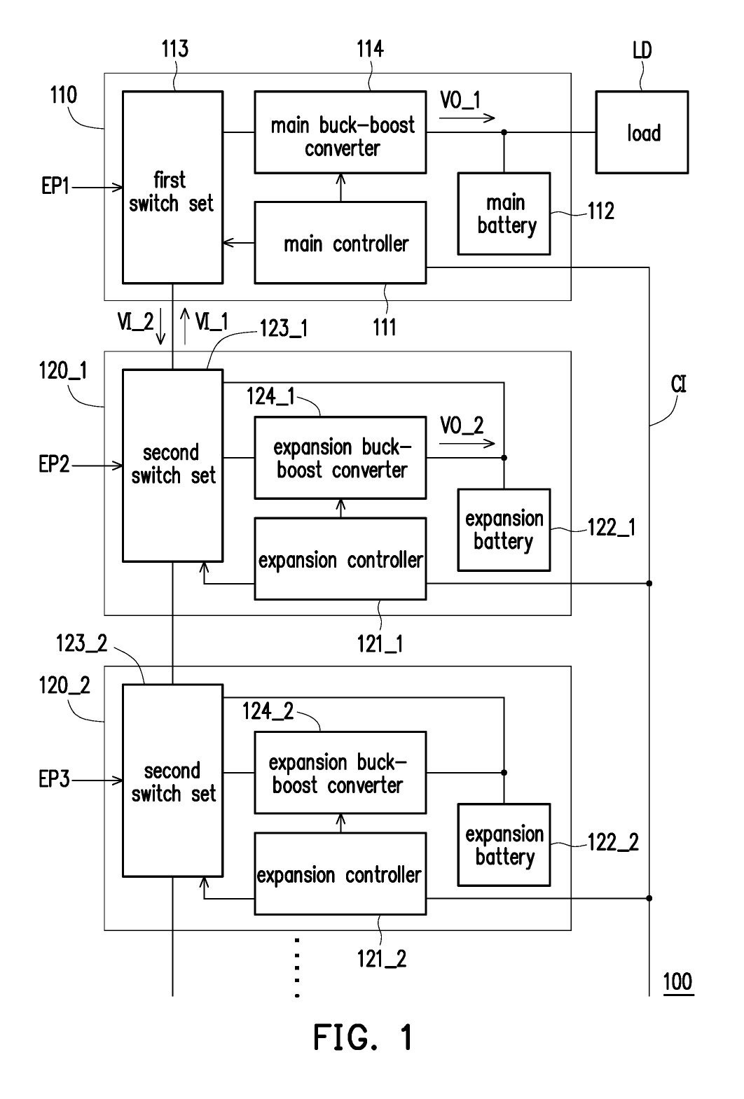

Referring to FIG. 1, FIG. 1 is a schematic diagram of a power storage apparatus according to the first embodiment of the disclosure. In this embodiment, the power storage apparatus 100 includes a system host 110, battery expansion modules 120_1 and 120_2, and a communication interface CI. The system host 110 includes a main controller 111, a main battery 112, a first switch set 113, and a main buck-boost converter 114. The main controller 111 is used as the control core of the system host 110. The main battery 112 is used to store a first DC output voltage VO_1. The first switch set 113 is coupled between the main controller 111 and the main battery 112 and is controlled by the main controller. The main buck-boost converter 114 is coupled between the main controller 111, the main battery 112, and the first switch set 113. The main buck-boost converter 114 is used to receive control of the main controller 111 and convert a first DC input voltage VI_1 received by the first switch set 113 or an external power EP1 to output the first DC output voltage VO_1 to charge the main battery 112. In the disclosure, the number of the battery expansion modules may be one or more and is not particularly limited.

In this embodiment, the battery expansion modules 120_1 and 120_2 are adapted to be detachably assembled with the system host 110. The battery expansion module 120_1 includes an expansion controller 121_1, an expansion battery 122_1, a second switch set 123_1, and an expansion buck-boost converter 124_1. The battery expansion module 120_2 includes an expansion controller 121_2, an expansion battery 122_2, a second switch set 123_2, and an expansion buck-boost converter 124_2. Taking the battery expansion module 120_1 as an example, the expansion controller 121_1 is used as the control core of the battery expansion module 120_1, and the expansion controller 121_1 and the main controller 111 communicate with each other through the communication interface CI. The expansion battery 122_1 is used to store a second DC output voltage VO_2. The second switch set 123_1 is coupled between the expansion controller 121_1 and the expansion battery 122_1. The second switch set 123_1 is used to receive the power provided by an external power EP2 or the expansion battery 122_1 and provide the power received from the external power EP2 or the expansion battery 122_1 as the first DC input voltage VI_1. The expansion buck-boost converter 124_1 is coupled between the expansion controller 121_1, the second switch set 123_1, and the expansion battery 122_1. The expansion buck-boost converter 124_1 is used to receive control of the expansion controller 121_1 and convert a second DC input voltage VI_2 received by the first switch set 113 to output a second DC output voltage VO_2 to charge the expansion battery 122_1.

In this embodiment, the system host 110 of the power storage apparatus 100 may be connected to a load LD. The system host 110 is used to provide the power of the main battery 112 to the load LD. In some embodiments, the load LD may also be connected to the battery expansion modules 120_1/120_2. The battery expansion modules 120_1/120_2 may provide the power of the expansion batteries 122_1/122_2 to the load LD. In some embodiments, the power storage apparatus 100 may further provide one of the external powers EP1, EP2, and EP3 to the load LD.

In this embodiment, when the system host 110 and the battery expansion modules 120_1 and 120_2 are assembled, the main controller 111 and the expansion controllers 121_1 and 121_2 communicate with each other through the communication interface CI and the first switch set 113 and the second switch sets 123_1 and 123_2 are assembled to form a switch set. The main controller 111 may determine the power amount of the main battery 112 and determine whether the system host 110 receives the external power EP1. The expansion controller 121_1 may determine the power amount stored in the expansion battery 122_1 and determine whether the battery expansion module 120_1 receives the external power EP2. In addition, the expansion controller 121_2 may determine the power amount stored in the expansion battery 122_2 and determine whether the battery expansion module 120_2 receives the external power EP3. The main controller 111 and the expansion controllers 121_1 and 121_2 cooperatively control the first switch set 113 and the second switch sets 123_1 and 123_2 through the communication interface CI according to the above determination results, so as to selectively charge the main battery 112 or the expansion batteries 122_1 and 122_2.

With the mechanism of cooperative control and selective charging as described above, the charging efficiency of the power storage apparatus 100 does not decrease as the number of battery expansion modules increases. With the mechanism of cooperative control and selective charging as described above, it is also possible to prevent imbalance caused by the assembly of multiple battery expansion modules 120_1 and 120_2, thereby reducing a discharge surge of the main battery 112 or the expansion batteries 122_1 and 122_2 to extend the lifespan of the main battery 112 or the expansion batteries 122_1 and 122_2.

The system host 110 converts the first DC input voltage VI_1 through the main buck-boost converter 114 to generate the first DC output voltage VO_1 that matches the power specification of the main battery 112. The battery expansion modules 120_1 and 120_2 may respectively convert the second DC input voltage VI_2 through the expansion buck-boost converters 124_1 and 124_2 to generate the second DC output voltage VO_2 that matches the power specification of the expansion batteries 122_1 and 122_2. Thus, the power storage apparatus 100 may receive power of different power specifications to charge the main battery 112 or the expansion batteries 122_1 and 122_2, thereby improving the battery expansibility of the power storage apparatus 100.

Hereinafter, the assembly of the system host 110 and the battery expansion module 120_1 is taken as an example. When the main controller 111 and the expansion controller 121_1 communicate with each other through the communication interface CI, the main controller 111 may determine whether the first switch set 113 is connected to the external power EP1 and the expansion controller 121 may determine whether the first switch set 113 is connected to the external power EP2. The main controller 111 and the expansion controllers 121_1 and 121_2 control the first switch set 113 to receive the external power EP1 or the first DC input voltage VI_1 that the second switch set 123_1 provides by receiving the external power EP1 according to the above determination results. The main buck-boost converter 114 converts the external power EP1 or the first DC input voltage VI_1 received by the first switch set 113 to output the first DC output voltage VO_1 to charge the main battery 112.

Hereinafter, the assembly of the system host 110 and the battery expansion module 120_1 is taken as another example. When the main controller 111 and the expansion controller 121_1 communicate with each other through the communication interface CI, the expansion controller 121_1 may determine whether the power amount stored in the expansion battery 122_1 is greater than a predetermined minimum discharge amount. If the power amount stored in the expansion battery 122_1 is greater than the predetermined minimum discharge amount, the expansion controller 121_1 controls the second switch set 123_1 to provide the power of the expansion battery 122_1 as the first DC input voltage VI_1. The second switch set 123_1 provides the first DC input voltage VI_1 to the first switch set 113, and the main buck-boost converter 114 converts the first DC input voltage VI_1 received by the first switch set 113 to output the first DC output voltage VO_1 to charge the main battery 112. On the other hand, if the power amount stored in the expansion battery 122_1 is not greater than the predetermined minimum discharge amount, the expansion controller 121_1 controls the second switch set 123_1 not to provide the power of the expansion battery 122_1 as the first DC input voltage VI_1.

Hereinafter, the assembly of the system host 110 and the battery expansion module 120_1 is taken as another example. When the main controller 111 and the expansion controller 121_1 communicate with each other through the communication interface CI, the expansion controller 121_1 is further used to determine whether the second switch set 123_1 receives the external power EP2 and the main controller 111 is further used to determine whether the power amount stored in the main battery 112 reaches a fully charged state. If the expansion controller 121_1 determines that the second switch set 123_1 receives the external power EP2 and the main controller 111 determines that the power amount of the main battery 112 reaches the fully charged state, the expansion controller 121_1 controls the second switch set 123_1 to provide the external power EP2 as the first DC input voltage VI_1 and provide the first DC input voltage VI_1 to the expansion buck-boost converter 124_1. The expansion buck-boost converter 124_1 converts the external power EP2, so as to output the second DC output voltage VO_2 to charge the expansion battery 122_1.

Hereinafter, the assembly of the system host 110 and the battery expansion module 120_1 is again taken as another example. The main controller 111 is further used to determine whether the first switch set 113 receives the external power EP1. If the main controller 111 determines that the first switch set 113 receives the external power EP1 and determines that the main battery 112 reaches the fully charged state, the main controller 111 controls the first switch set 113 to provide the received second converted DC voltage as the second DC input voltage VI_2 and to provide the second DC input voltage VI_2 to the second switch set 123_1, and the expansion buck-boost converter 124_1 converts the second DC input voltage VI_2 received by the second switch set 123_1 to output the second DC output voltage VO_2 to charge the expansion battery 122_1.

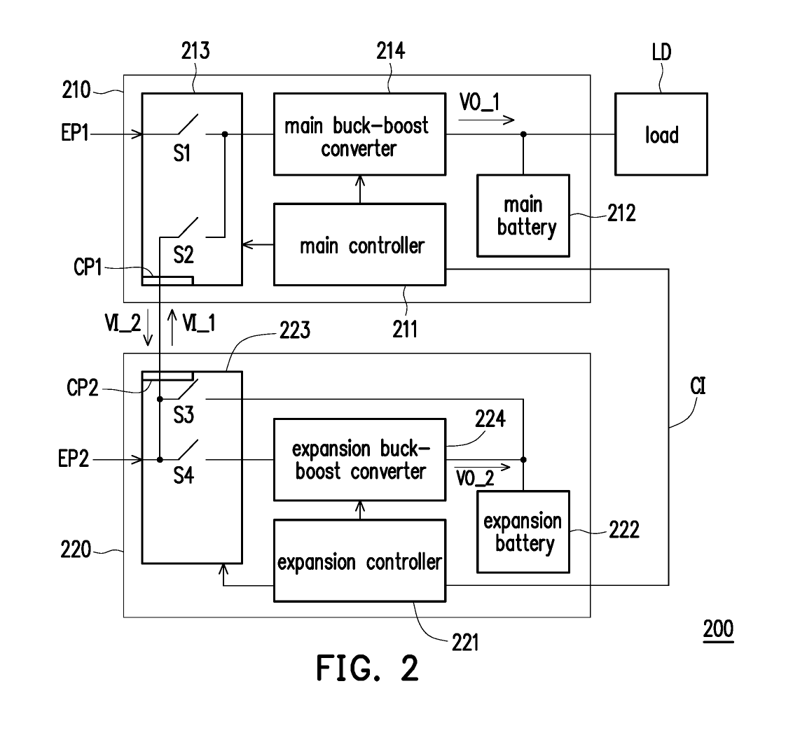

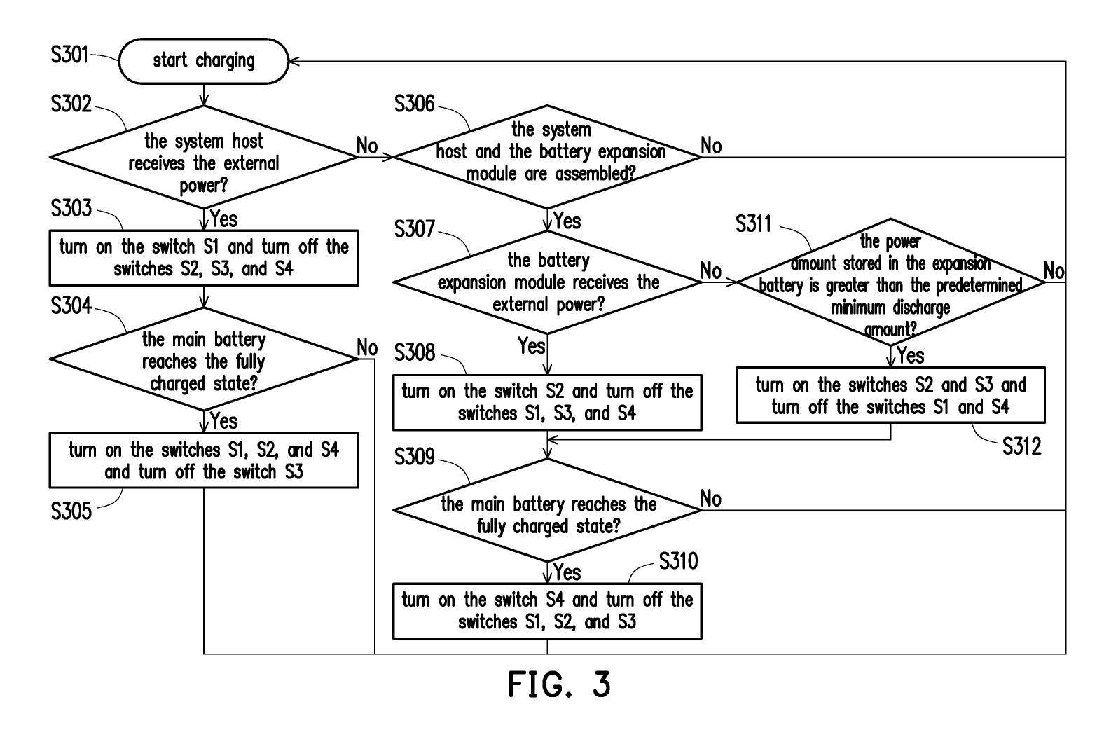

An operation that the power storage apparatus performs on the first switch set and the second switch set is described in detail hereinafter. Referring to FIG. 2 and FIG. 3, FIG. 2 is a schematic diagram of the power storage apparatus according to the second embodiment of the disclosure. FIG. 3 is a flowchart illustrating the operation that the power storage apparatus performs on the first switch set and the second switch set according to the second embodiment of the disclosure. In this embodiment, the power storage apparatus 200 includes a system host 210 and a battery expansion module 220.

A first switch set 213 of the system host 210 includes a first switch set connection port CP1, a first switch S1, and a second switch S2. The first terminal of the first switch S1 is used to receive the external power EP1 and the second terminal of the first switch S1 is coupled to a main buck-boost converter 214. The first terminal of the second switch S2 is coupled to the first switch set connection port CP1 and the second terminal of the second switch S2 is coupled to the second terminal of the first switch S1 and the main buck-boost converter 214. A second switch set 223 of the battery expansion module 220 includes a second switch set connection port CP2, a third switch S3, and a fourth switch S4. The first terminal of the third switch S3 is coupled to the second switch set connection port CP2 and the second temiinal of the third switch S3 is coupled to the expansion battery 222. The first terminal of the fourth switch S4 is coupled to the second switch set connection port CP2 and the first terminal of the third switch S3. The second terminal of the fourth switch S4 is coupled to an expansion buck-boost converter 224. The first switch S1, the second switch S2, the third switch S3, and the fourth switch S4 of this embodiment may be transistor switches of any form.

In this embodiment, when the system host 210 and the battery expansion module 220 are assembled, the main controller 211 and the expansion controller 221 start to cooperatively control the first switch set 213 and the second switch set 223. The system host 210 starts charging in step S301. In step S302, the main controller 211 determines whether the system host 210 receives the external power EP1, that is, determines whether the first terminal of the first switch S1 receives the external power EP1. If the main controller 211 determines that the first terminal of the first switch S1 receives the external power EP1, the procedure proceeds to step S303. In step S303, the main controller 211 turns on the first switch S1 and turns off the second switch S2. In addition, if the expansion controller 221 determines that the system host 210 and the battery expansion module 220 are assembled, the third switch S3 and the fourth switch S4 are turned off. Thus, the first switch set 213 provides the power of the external power EP1 to the main buck-boost converter 214 under control of the main controller 211, and the main buck-boost converter 214 converts the power of the external power EP1 to output the first DC output voltage VO_1 to charge the main battery 212.

In step S304, if the main controller 211 determines that the first terminal of the first switch S1 receives the external power, the main controller 211 further determines whether the main battery 212 reaches the fully charged state. If the main controller 211 determines that the main battery 212 reaches the fully charged state, the procedure proceeds to step S305. In step S305, the main controller 211 turns on the first switch S1 and the second switch S2. In addition, if the expansion controller 221 determines that the system host 210 and the battery expansion module 220 are assembled, the fourth switch S4 is turned on and the third switch S3 is turned off. Thus, the first switch set 213 uses the external power EP1 as the second DC input voltage V1_2 under control of the main controller 211 and provides the second DC input voltage VI_2 to the second switch set 223. The expansion buck-boost converter 224 converts the second DC input voltage VI_2 received by the second switch set 223 to output the second DC output voltage VO_2 to charge the expansion battery 222. In other words, if the main controller 211 deter wines that the first switch set 213 receives the external power EP1 and determines that the main battery 212 reaches the fully charged state, the main controller 211 controls the first switch set 213 to provide the external power EP1 to the battery expansion module 220 to charge the expansion battery 222.

On the other hand, if the main controller 211 determines in step S304 that the main battery 212 does not reach the fully charged state, the procedure returns to step S301.

Returning to step S302, if the main controller 211 determines that the system host 210 does not receive the external power EPI, the procedure proceeds to step S306. In step S306, the main controller 211 again confirms whether the system host 210 and the battery expansion module 220 are assembled. If the main controller 211 determines that the system host 210 and the battery expansion module 220 are assembled, the procedure proceeds to step S307. On the other hand, if the main controller 211 deteimines that the system host 210 is not connected to the battery expansion module 220, the procedure returns to step S301. In step S307, the expansion controller 221 determines whether the battery expansion module 220 receives the external power EP2. If the expansion controller 221 determines that the battery expansion module 220 receives the external power EP2, that is, if the expansion controller 221 deteii 1ines that the first terminal of the fourth switch S4 receives the external power EP2, the procedure proceeds to step S308. In step S308, the expansion controller 221 turns off the third switch S3 and the fourth switch S4 and the main controller 211 turns on the second switch S2 and turns off the first switch S1. Thus, the second switch set 223 uses the external power EP2 as the first DC input voltage VI_1 under control of the expansion controller 221 and provides the first DC input voltage VI_1 to the first switch set 213. The main buck-boost converter 214 converts the first DC input voltage VI_1 received by the first switch set 213 so as to output the first DC output voltage VO_1 to charge the main battery 212.

Next, the main controller 211 determines in step S309 whether the main battery 212 reaches the fiilly charged state. If the main controller 211 determines that the main battery 212 reaches the frilly charged state, the procedure proceeds to step S310. In step S310, the main controller 211 turns off the first switch S1 and the second switch S2 and the expansion controller 221 turns on the fourth switch S4 and turns off the third switch S3. Thus, the second switch set 223 provides the external power EP2 to the expansion buck-boost converter 224 under control of the expansion controller 221. The expansion buck-boost converter 224 receives the external power EP2 and converts the external power EP2 to output the second DC output voltage VO_2 to charge the expansion battery 222. In other words, if the expansion controller 221 determines that the second switch set 223 receives the external power EP2 and the main controller 211 determines that the power amount of the main battery 212 reaches the fully charged state, the expansion controller 221 controls the second switch set 223 to provide the power of the external power EP2 to the expansion battery 222 for charging. On the other hand, if the main controller 211 determines that the main battery 212 does not reach the fully charged state, the procedure returns to step S301.

Returning to step S307, if the expansion controller 221 determines that the battery expansion module 220 does not receive the external power EP2, the procedure proceeds to step S311. The expansion controller 221 determines in step S311 whether the power amount stored in the expansion battery 222 is greater than the predetermined minimum discharge amount. If the expansion controller 221 determines that the power amount stored in the expansion battery 222 is greater than the predetermined minimum discharge amount, that is, if the expansion controller 221 determines that the first terminal of the fourth switch S4 does not receive the external power EP2, the procedure proceeds to step S312. In step S312, the expansion controller 221 turns on the third switch S3 and turns off the fourth switch S4 and the main controller 211 turns on the second switch S2 and turns off the first switch S 1. Thus, the second switch set 223 provides the power of the expansion battery 222 as the first DC input voltage VI_1 under control of the expansion controller 221 and provides the first DC input voltage VI_1 to the first switch set 213. The main buck-boost converter 214 converts the first DC input voltage VI_1 received by the first switch set 213 so as to output the first DC output voltage VO_1 to charge the main battery 212. After step S312 is completed, the procedure proceeds to step S309. Furthermore, in step S311, if the expansion controller 221 determines that the power amount stored in the expansion battery 222 is not greater than the predetermined minimum discharge amount, the procedure returns to step S301.

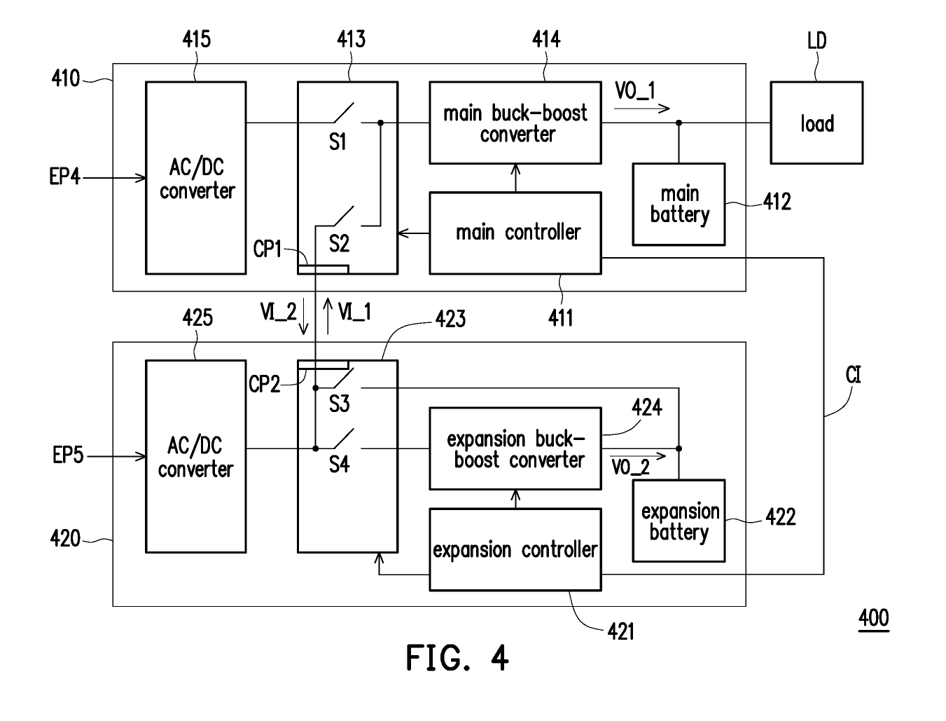

Referring to FIG. 4, FIG. 4 is a schematic diagram of the power storage apparatus according to the third embodiment of the disclosure. Different from the second embodiment, a system host 410 of this embodiment further includes an AC/DC converter 415 and a battery expansion module 420 further includes an AC/DC converter 425. The AC/DC converter 415 of the system host 410 is coupled to a first switch set 413. The AC/DC converter 415 is used to receive an external power EP4 in the form of AC power and convert the external power EP4 to generate power in the form of DC power. The AC/DC converter 425 of the battery expansion module 420 is coupled to a second switch set 423. The AC/DC converter 425 is used to receive an external power

EP5 in the form of AC power and convert the external power EP5 to generate power in the form of DC power.

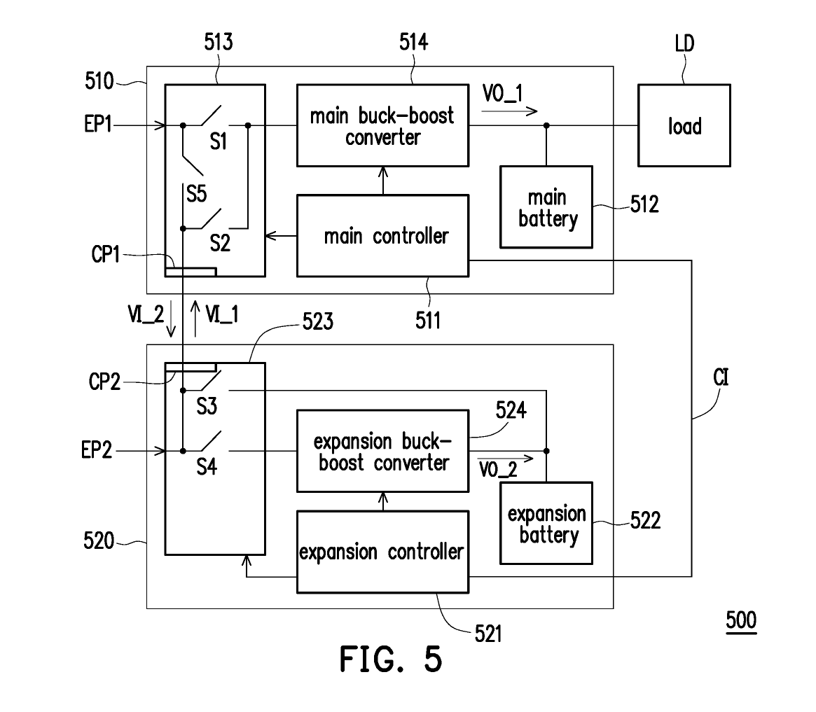

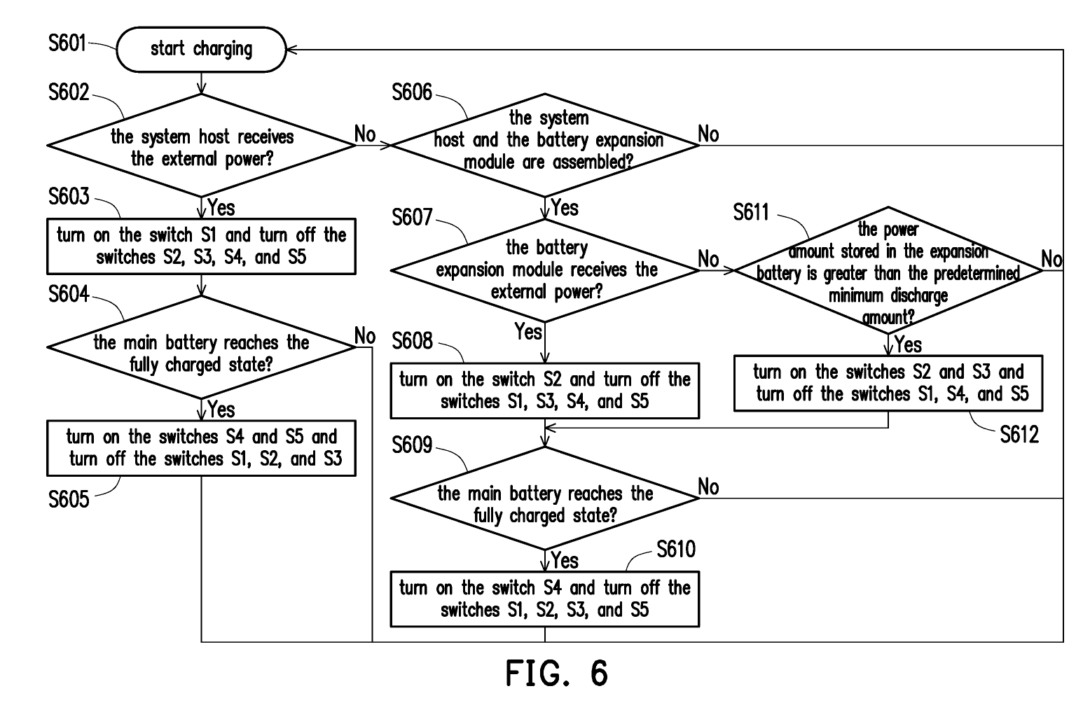

Referring to FIG. 5 and FIG. 6, FIG. 5 is a schematic diagram of the power storage apparatus according to the fourth embodiment of the disclosure. FIG. 6 is a flowchart illustrating an operation that the power storage apparatus performs on the first switch set and the second switch set according to the fourth embodiment of the disclosure. Different from the second embodiment, in a system host 510, a first switch set 513 further includes a fifth switch S5. The first terminal of the fifth switch S5 is coupled to the first terminal of the first switch S1. The second terminal of the fifth switch S5 is coupled to the first terminal of the second switch S2 and the first switch set connection port CP1. The fifth switch S5 of this embodiment may be a transistor switch of any form.

In the operation procedure of this embodiment, the system host 510 starts charging in step S601. In step S602, the main controller 511 determines whether the system host 510 receives the external power EP1. If the main controller 511 determines that the system host 510 receives the external power EP1, the procedure proceeds to step S603. In step S603, the main controller 511 turns on the first switch S1 and turns off the second switch S2 and the fifth switch S5, so as to charge the main battery 512. In addition, if the expansion controller 521 determines that the system host 510 and the battery expansion module 520 are assembled, the third switch S3 and the fourth switch S4 are turned off.

In step S604, the main controller 511 determines whether the main battery 512 reaches the fully charged state. If the main controller 511 determines that the main battery 512 reaches the fully charged state, the procedure proceeds to step S605. In step S605, the main controller 511 turns on the fifth switch S5 and turns off the first switch S1 and the second switch S2. In addition, if the expansion controller 521 determines that the system host 510 and the battery expansion module 520 are assembled, the fourth switch S4 is turned on and the third switch S3 is turned off, so as to charge the expansion battery 522.

It is worth mentioning that, in step S605, the main controller 511 turns on the fifth switch S5 instead of turning on the first switch S1 and the second switch S2. As a result, the transmission loss of the external power EP1 in the first switch set 513 is reduced.

If the main controller 511 determines in step S604 that the main battery 512 does not reach the fully charged state, the procedure returns to step S601.

Returning to step S602, if the main controller 511 determines that the system host 510 does not receive the external power EP1, the procedure proceeds to step S606. In step S606, the main controller 511 again determines whether the system host 510 and the battery expansion module 520 are assembled. If the main controller 511 determines that the system host 510 and the battery expansion module 520 are assembled, the procedure proceeds to step S607. On the other hand, if the main controller 511 determines that the system host 510 and the battery expansion module 520 are not assembled, the procedure returns to step S601. In step S607, the expansion controller 521 determines whether the battery expansion module 520 receives the external power EP2. If the expansion controller 521 determines that the battery expansion module 520 receives the external power EP2, the procedure proceeds to step S608. In step S608, the expansion controller 521 turns off the third switch S3 and the fourth switch S4 and the main controller 511 turns on the second switch S2 and turns off the first switch S1 and the fifth switch S5, so as to charge the main battery 512.

Next, the main controller 511 determines in step S609 whether the main battery 512 reaches the fully charged state. If the main controller 511 determines that the main battery 512 reaches the fully charged state, the procedure proceeds to step S610. In step S610, the main controller 511 turns off the first switch S1, the second switch S2, and the fifth switch S5 and the expansion controller 521 turns on the fourth switch S4 and turns off the third switch S3, so as to charge the expansion battery 522.

Returning to step S607, if the expansion controller 521 determines that the battery expansion module 520 does not receive the external power EP2, the procedure proceeds to step S611. The expansion controller 521 determines in step S611 whether the power amount stored in the expansion battery 522 is greater than the predetermined minimum discharge amount. If the expansion controller 521 determines that the power amount stored in the expansion battery 522 is greater than the predetermined minimum discharge amount, the procedure proceeds to step S612. In step S612, the expansion controller 521 turns on the third switch S3 and turns off the fourth switch S4 and the main controller 511 turns on the second switch S2 and turns off the first switch S1 and the fifth switch S5, so as to charge the main battery 512. After step S612 is completed, the procedure proceeds to step S609. On the other hand, in step S611, if the expansion controller 521 determines that the power amount stored in the expansion battery 522 is not greater than the predetermined minimum discharge amount, the procedure returns to step S601.

To sum up, when the system host and the battery expansion module of the disclosure are assembled, the first switch set and the second switch set may be controlled cooperatively through the communication interface, so as to selectively charge the main battery or the expansion battery. In addition, the system host may convert the first DC input voltage through the main buck-boost converter to generate the first DC output voltage that matches the power specification of the main battery. The battery expansion module may convert the second DC input voltage through the expansion buck-boost converter to generate the second DC output voltage that matches the power specification of the expansion battery. Thus, the power storage apparatus may receive power of different power specifications to charge the main battery or the expansion batteries, thereby improving the battery expansibility of the power storage apparatus. Furthermore, with the mechanism of cooperative control and selective charging of the disclosure, the charging efficiency of the power storage apparatus does not decrease as the number of battery expansion modules increase, and the imbalance caused by assembly of multiple battery expansion modules may also be prevented to extend the lifespan of the main battery 112 or the expansion batteries 122_1 and 122_2.

It will be apparent to those skilled in the art that various modifications and variations can be made to the disclosed embodiments without departing from the scope or spirit of the disclosure. In view of the foregoing, it is intended that the disclosure covers modifications and variations provided that they fall within the scope of the following claims and their equivalents.

What is claimed is:

1. A power storage apparatus, comprising:
a system host, comprising:
a main controller;
a main battery;
a first switch set coupled between the main controller and the main battery; and
a main buck-boost converter coupled to the main controller, the first switch set, and the main battery to receive control of the main controller and convert a first DC input voltage received by the first switch set to output a first DC output voltage to charge the main battery;
a battery expansion module adapted to be detachably assembled with the system host, and the battery expansion module comprising:
an expansion controller;
an expansion battery; and
a second switch set coupled between the expansion controller and the expansion battery; and
a communication interface, wherein when the system host and the battery expansion module are assembled, the expansion controller and the main controller communicate with each other through the communication interface and selectively control switches of the first switch set and the second switch set to charge the main battery or the expansion battery.

2. The power storage apparatus according to claim 1, wherein if the expansion controller determines that a power amount stored in the expansion battery is greater than a predetermined minimum discharge amount, the expansion controller controls the second switch set to provide power of the expansion battery to the first switch set to charge the main battery.

3. The power storage apparatus according to claim 1, wherein the battery expansion module further comprises:
an expansion buck-boost converter coupled to the expansion controller, the second switch set, and the expansion battery to receive control of the expansion controller and convert a second DC input voltage received by the first switch set to output a second DC output voltage to charge the expansion battery.

4. The power storage apparatus according to claim 1, wherein if the expansion controller determines that the second switch set receives an external power and the main controller determines that a power amount of the main battery reaches a fully charged state, the expansion controller controls the second switch set to provide the external power to the expansion battery for charging.

5. The power storage apparatus according to claim 1, wherein if the main controller determines that the first switch set receives an external power and determines that the main battery reaches the fully charged state, the main controller controls the first switch set to provide the external power to the expansion battery for charging.

6. The power storage apparatus according to claim 1, wherein:
the first switch set comprises:
a first switch set connection port;
a first switch, a first terminal of the first switch being configured to receive an external power and a second terminal of the first switch being coupled to the main buck-boost converter; and
a second switch, a first terminal of the second switch being coupled to the first switch set connection port and a second tenninal of the second switch being coupled to the second terminal of the first switch and the main buck-boost converter; and
the second switch set comprises:
a second switch set connection port;
a third switch, a first terminal of the third switch being coupled to the second switch set connection port and a second terminal of the third switch being coupled to the expansion battery; and
a fourth switch, a first terminal of the fourth switch being configured to receive the external power and the first terminal of the fourth switch being coupled to the second switch set connection port and the first terminal of the third switch, and a second tenninal of the fourth switch being coupled to the expansion buck-boost converter.

7. The power storage apparatus according to claim 6, wherein if the main controller determines that the first terminal of the first switch does not receive the external power and the expansion controller determines that the first terminal of the fourth switch receives the external power, the expansion controller turns off the third switch and the fourth switch and the main controller turns on the second switch and turns off the first switch to charge the main battery.

8. The power storage apparatus according to claim 6, wherein if the main controller determines that the first tenninal of the first switch does not receive the external power and the expansion controller determines that the first terminal of the fourth switch does not receive the external power, the expansion controller turns on the third switch and turns off the fourth switch and the main controller turns on the second switch and turns off the first switch to output power of the expansion battery to the main battery for charging.

9. The power storage apparatus according to claim 6, wherein if the main controller determines that the first terminal of the first switch receives the external power and the expansion controller determines that the first terminal of the fourth switch does not receive the external power, the main controller turns on the first switch and turns off the second switch and the expansion controller turns off the third switch and the fourth switch to charge the main battery.

10. The power storage apparatus according to claim 6, wherein if the expansion controller determines that the second switch set receives the external power and the main controller determines that the main battery reaches the fully charged state, the main controller turns off the first switch and the second switch and the expansion controller turns on the fourth switch and turns off the third switch to charge the expansion battery.

11. The power storage apparatus according to claim 6, wherein if the main controller determines that the first terminal of the first switch receives the external power and determines that the main battery reaches the fully charged state, the main controller turns on the first switch and the second switch and the expansion controller turns on the fourth switch and turns off the third switch to charge the expansion battery.

12. The power storage apparatus according to claim 6, wherein:
the first switch set further comprises:
a fifth switch, a first terminal of the fifth switch being coupled to the first terminal of the first switch and a second terminal of the fifth switch being coupled to the first terminal of the second switch and the first switch set connection port,
wherein if the main controller determines that the first terminal of the first switch receives the external power and the main battery reaches the fully charged state, the main controller turns on the fifth switch and turns off the first switch and the second switch and the expansion controller turns on the fourth switch and turns off the third switch to charge the expansion battery.
